(19) United States
(12) Patent Application Publication
(10) Pub. No.: US 2014/0077149 A1
(43) Pub. Date: Mar. 20, 2014

(54) RESISTANCE MEMORY CELL, RESISTANCE MEMORY ARRAY AND METHOD OF FORMING THE SAME

(71) Applicants: Frederick T. Chen, Hsinchu County (TW); Heng-Yuan Lee, Hsinchu County (TW); Yu-Sheng Chen, Taoyuan County (TW); Wei-Su Chen, Hsinchu City (TW); Tai-Yuan Wu, Taipei City (TW); Pang-Hsu Chen, Hsinchu City (TW)

(72) Inventors: Frederick T. Chen, Hsinchu County (TW); Heng-Yuan Lee, Hsinchu County (TW); Yu-Sheng Chen, Taoyuan County (TW); Wei-Su Chen, Hsinchu City (TW); Tai-Yuan Wu, Taipei City (TW); Pang-Hsu Chen, Hsinchu City (TW)

(73) Assignee: INDUSTRIAL TECHNOLOGY RESEARCH INSTITUTE, Hsinchu (TW)

(21) Appl. No.: 13/615,683

(22) Filed: Sep. 14, 2012

(51) Int. Cl. H01L 27/24; H01L 45/00

(52) U.S. Cl. 257/5; 257/2; 438/382; 257/E27.004; 257/E45.003

(57) ABSTRACT

A resistance memory cell including a variable resistance layer is provided. The variable resistance layer includes at least one dominant resistance layer and at least one auxiliary resistance layer. The dominant resistance layer(s) and the auxiliary resistance layer(s) in totality form a closed ion exchange system, the exchanged ions are comparably mobile in each of the dominant resistance layer(s) and the auxiliary resistance layer(s), and the maximum resistance of the at least one dominant resistance layer is higher than that of the at least one auxiliary resistance layer.

### TECHNICAL FIELD

The disclosure relates to a resistance memory cell, a resistance memory array and a method of forming the same.

### BACKGROUND

Memory devices developed based on semiconductor techniques, such as dynamic random access memory (DRAM), static random access memory (SRAM), and non-volatile memory, have played a major part in today's semiconductor industry. These memories have been broadly applied to personal computers, mobile phones, and networks and have become one of the most indispensable electronic products in our daily life.

The demand for memories having low power consumption, low cost, high access speed, small volume, and high capacity has been increasing drastically along with the widespread of consumable electronic products and system products. Recording data by changing the resistance of a variable-resistance layer is a promising alternative to storing charge or magnetization.

In a resistive random access memory (RRAM), the state of a variable resistance layer is changed by applying a current pulse and a conversion voltage, so as to switch between a set state and a reset state according to different resistances. The digital data “0” and “1” is recorded in the memory according to the set and reset states corresponding to different resistances.

However, the conventional RRAM cannot serve practically as a multi-level memory, due to the need for greater resistance precision. In addition, reliable operation of memory or storage requires predictable mechanisms to be understood and applied.

### SUMMARY

One of the embodiments provides a resistance memory cell including a variable resistance layer. The variable resistance layer includes at least one dominant resistance layer and at least one adjacent auxiliary resistance layer, wherein the dominant resistance layer(s) and the auxiliary resistance layer(s) in totality form a closed ion exchange system, the exchanged ions are comparably mobile in each of the dominant resistance layer(s) and the auxiliary resistance layer(s), and the maximum resistance of the at least one dominant resistance layer is higher than that of the at least one auxiliary resistance layer.

One of the embodiments provides a method of forming a resistance memory array, which includes: forming a plurality of insulation layers and a plurality of bit line layers arranged alternately on a substrate, wherein at least one barrier opening is formed through the insulation layers and the bit line layers; patterning the insulation layers and the bit line layers, so as to form at least two stacked structures with the barrier opening therebetween; forming a dielectric layer between and outside of the stacked structures; forming a first word line trench opening in the dielectric layer between the stacked structures and forming two second word line trench openings in the dielectric layer respectively at outer sides of the stacked structures; forming a variable resistance layer including at least one dominant resistance layer and at least one adjacent auxiliary resistance layer to cover the stacked structures and fill in the first and second word line trench openings, wherein the dominant resistance layer(s) and the auxiliary resistance layer(s) in totality form a closed ion exchange system, the exchanged ions are comparably mobile in each of the dominant resistance layer(s) and the auxiliary resistance layer(s), and a maximum resistance of a dominant resistance layer is higher than that of an auxiliary resistance layer; and forming a word line layer on the variable resistance layer.

One of the embodiments provides a resistance memory array including at least two separate stacked structures, a variable resistance layer and a word line layer. The stacked structures are disposed on a substrate, wherein each stacked structure includes a plurality of insulation layers and a plurality of bit line layers arranged alternately, and a barrier opening is formed between the stacked structures. The variable resistance layer including at least one dominant resistance layer and at least one adjacent auxiliary resistance layer is disposed on the substrate and covers the stacked structures, wherein the dominant resistance layer(s) and the auxiliary resistance layer(s) in totality form a closed ion exchange system, the exchanged ions are comparably mobile in each of the dominant resistance layer and the auxiliary resistance layer, and the maximum resistance of the at least one dominant resistance layer is higher than that of the at least one auxiliary resistance layer. The word line layer is disposed on the variable resistance layer.

In order to make the aforementioned and other objects, features and advantages of the disclosure comprehensible, a preferred embodiment accompanied with figures is described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic cross-sectional view illustrating a resistance memory cell according to a first embodiment of the disclosure.

FIG. 2 is a schematic I-V curve of a resistance memory cell according to an embodiment of the disclosure.

FIG. 3A and FIG. 3B are schematic views respectively illustrating an oxygen ion exchange in a resistance memory cell according to an embodiment of the disclosure.

FIG. 3C is a schematic view illustrating ion exchange between a dominant resistance layer and adjacent auxiliary resistance layers on both sides, according to an embodiment of the disclosure.

FIG. 3D is a schematic view illustrating ion exchange among a pair of adjacent dominant resistance layers, and auxiliary resistance layers adjacent to the dominant resistance layers.

FIG. 4A to FIG. 4D are schematic cross-sectional views illustrating a method of forming a resistance memory array according to a second embodiment of the disclosure.

FIG. 4D-1 is a schematic cross-sectional view of another resistance memory array according to the second embodiment of the disclosure.

FIG. 4D-2 is a schematic cross-sectional view of yet another resistance memory array according to the second embodiment of the disclosure.

FIG. 4D-3 is a schematic cross-sectional view of still another resistance memory array according to the second embodiment of the disclosure.

FIG. 5 is a schematic top view of FIG. 4B.

FIG. 6 is a schematic top view of FIG. 4C.

FIG. 7 is a schematic top view within one plane of the bit line layers according to the second embodiment of the disclosure.

### DETAILED DESCRIPTION OF EMBODIMENTS OF THE DISCLOSURE

Reference will now be made in detail to the embodiments of the disclosure, examples of which are illustrated in the accompanying drawings. Wherever possible, the same reference numbers are used in the drawings and the description to refer to the same or like parts.

### First Embodiment

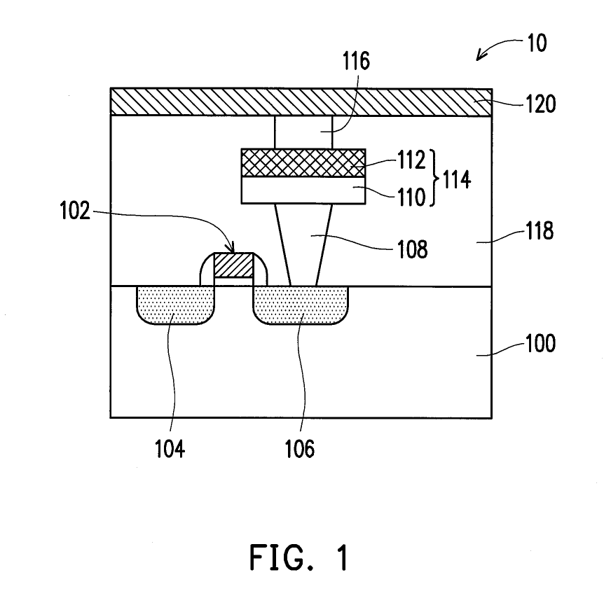

FIG. 1 is a schematic cross-sectional view illustrating a resistance memory cell according to a first embodiment of the disclosure. Referring to FIG. 1, the resistance memory cell 10 of the first embodiment includes a substrate 100, a gate structure 102, doped regions 104 and 106, a contact plug 108, a variable resistance layer 114, a conductive layer 116, a dielectric layer 118 and a bit line 120.

The substrate 100 can be a semiconductor substrate, such as a silicon substrate. The gate structure 102 is disposed on the substrate 100. The gate structure 102 includes a conductive material, such as doped polysilicon. The doped regions 104 and 106 are disposed in the substrate 100 beside the gate structure 102. The contact plug 108 is disposed on the substrate 100 and is electrically connected to one of the doped regions 104 and 106. In this embodiment, the doped region 104 serves as a source region, the doped region 106 serves as a drain region, and the contact plug 108 is electrically connected to the doped region 106. The contact plug 108 includes metal, such as titanium, titanium nitride, and tungsten. Furthermore, the bit line 120 is disposed over the substrate 100 and across the gate structure 102. The bit line 120 is isolated from the gate structure 102 by the dielectric layer 118. The bit line 120 may be disposed on the dielectric layer 118. The dielectric layer 118 includes silicon oxide, silicon nitride or silicon oxynitride. The bit line 120 includes a conductive material, such as tungsten, aluminium or copper. Also, the variable resistance layer 114 is disposed on the contact plug 108 and is electrically connected between the contact plug 108 and the bit line 120.

As shown in FIG. 1, the variable resistance layer 114 of the embodiment is located within the dielectric layer 118. Between the variable resistance layer 114 and the bit line 120, there can be a conductive layer 116 used as a top electrode. The material of the top electrode can be, for example but not limited to, iridium, platinum, iridium oxide, titanium nitride, titanium aluminum nitride, ruthenium or ruthenium oxide. Also, between the variable resistance layer 114 and the contact plug 108, there can be another conductive layer (not shown) used as a bottom electrode. The material of the bottom electrode can be, for example but not limited to, iridium, platinum, iridium oxide, titanium nitride, titanium aluminum nitride, ruthenium, ruthenium oxide or polysilicon.

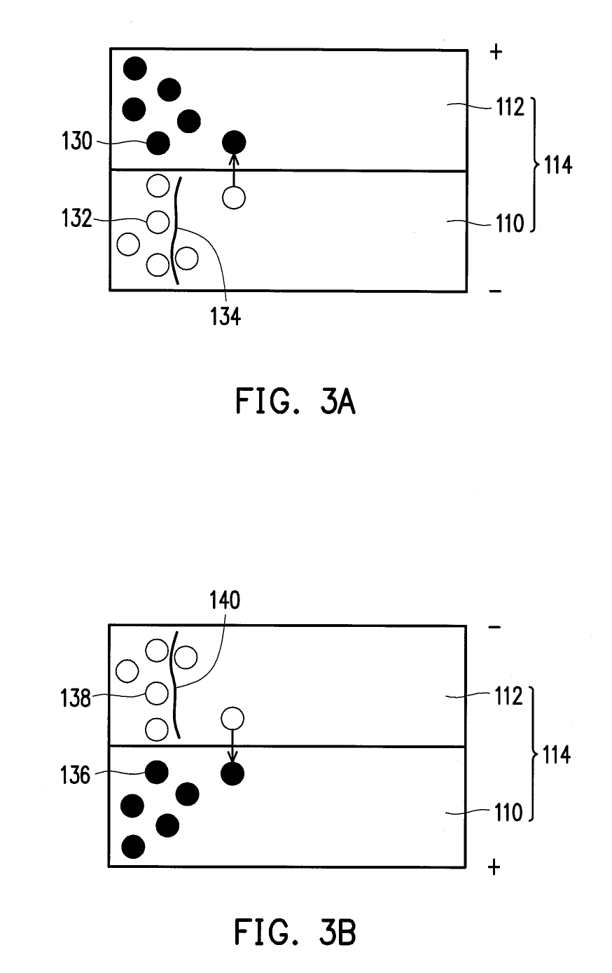

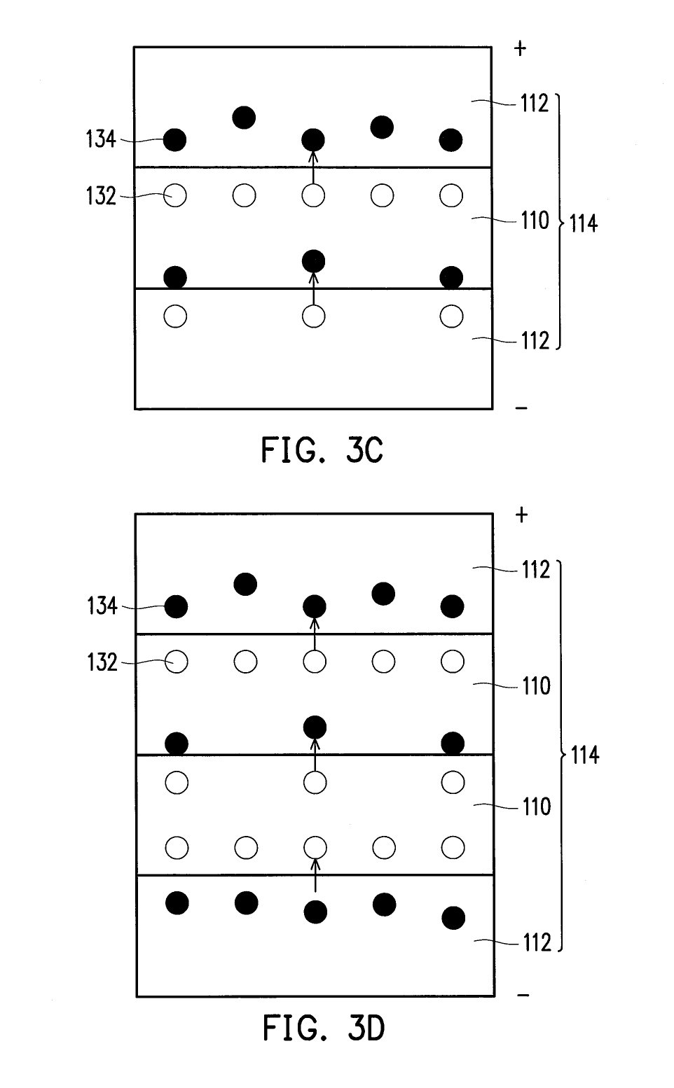

It is noted that the variable resistance layer 114 of the embodiment includes at least one dominant resistance layer 110 and at least one adjacent auxiliary resistance layer 112. The dominant resistance layer 110 and the auxiliary resistance layer 112 mutually exchange ions, and thereby change resistance. In other words, the resistance memory of the disclosure is a resistance memory based on ionic exchange. In FIG. 1, one dominant resistance layer 110 and one auxiliary resistance layer 112 are illustrated, and the auxiliary resistance layer 112 is disposed on the dominant resistance layer 110. However, the disclosure is not limited thereto. In another embodiment (not shown), the auxiliary resistance layer 112 can be disposed below the dominant resistance layer 110. Also, the number of the dominant resistance layer 110 and the number of the auxiliary resistance layer 112 are not limited by the disclosure. For example, the variable resistance layer 114 may include one dominant resistance layer 110 and two auxiliary resistance layers 112 beside the dominant resistance layer 110, as shown in FIG. 3C. The variable resistance layer 114 may include a pair of adjacent dominant resistance layers 110 and a pair of auxiliary resistance layers 112 adjacent to the dominant resistance layers 110 and respectively at the outer sides of the dominant resistance layers 110, as shown in FIG. 3D.

In an embodiment, each of the dominant resistance layer 110 and the auxiliary resistance layer 112 includes an oxide, and the exchanged ion is an oxygen ion. The dominant resistance layer 110 includes HfO₂, ZrO₂, Al₂O₃ or Ta₂O₅. The auxiliary resistance layer 112 includes TiO₂, TaOₓ or TiO_{y}, where x is less than 2.5 and y is less than 2. In the case of oxygen ions, the layer receiving the oxygen ion becomes more resistive, while the layer losing the oxygen ion becomes less resistive. In another embodiment, the dominant resistance layer 110 includes an oxide, the auxiliary resistance layer 112 includes a chalcogenide or oxide doped with a metal (e.g. Cu or Ag), and the exchanged ion includes the metal ion, such as a copper ion or a silver ion. The dominant resistance layer 110 includes HfO₂, ZrO₂, Al₂O₃ or Ta₂O₅. The auxiliary resistance layer 112 includes one of SiO₂, GeTe, GeSe and GeS each doped with Cu or Ag. In the case of metal ions, the layer receiving the metal ion becomes less resistive, while the layer losing the metal ion becomes more resistive. For the metal ion case, it is assumed that the electrodes do not continually replenish the metal ion supply to the layer losing metal ions.

In order to operate optimally, some conditions can be imposed on these layers. First, the exchanged ions can be significantly and comparably mobile in each of the dominant resistance layer 110 and the auxiliary resistance layer 112. Hence, one layer can not strongly attach to the ions, as that would cause subsequent resistance switching operation to cease. Second, the maximum resistance of the dominant resistance layer 110 can be much higher than that of the auxiliary resistance layer 112. This allows a larger range of resistance values to be attained. Hence, the layers can be oxides of different metals, for example. Third, the dominant resistance layer 110 and the auxiliary resistance layer 112 can form a closed ion exchange system. In other words, neither electrode can supply metal ions to either of the two layers, nor allow non-metallic ions (e.g. oxygen ions) to escape the two layers by diffusion. For example, the dominant resistance layer 110 and the auxiliary resistance layer 112 can be encapsulated in a dielectric layer (e.g. dielectric layer 118 in FIG. 1), which also prevents the ions from diffusing out. Fourth, the initial resistance can be maximal, i.e., dominated by the dominant resistance layer 110. Ideally, for lower current operation, the dominant resistance layer 110 is in an insulating state and the auxiliary resistance layer 112 is initially metallic.

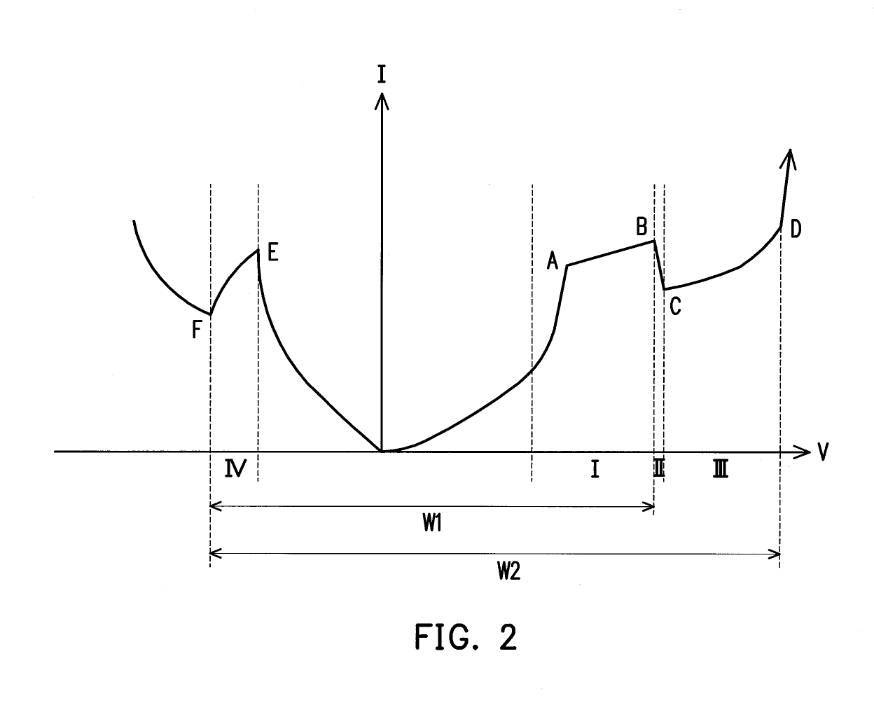

An initial forming operation under an applied voltage drives metal ions into the dominant resistance layer 110, or drives non-metallic ions (e.g. oxygen ions) into the auxiliary resistance layer 112. A percolating conducting path (“filament”) is formed in the dominant resistance layer 110. The filament behaviour is described in more detail below with reference to FIG. 2, FIG. 3A and FIG. 3B. FIG. 2 is a schematic I-V curve of a resistance memory cell according to an embodiment of the disclosure. FIG. 3A and FIG. 3B are schematic views respectively illustrating an oxygen ion exchange in a resistance memory cell according to an embodiment of the disclosure. FIG. 3C is a schematic view showing ion exchange between a single dominant resistance layer and two adjacent auxiliary resistance layers, one on each side of the dominant resistance layer, according to another embodiment of the disclosure. FIG. 3D is a schematic view showing ion exchange among a pair of dominant resistance layers, and auxiliary resistance layers, one located on either side of the pair of dominant resistance layers, according to yet another embodiment of the disclosure. In this case, the two dominant resistance layers may achieve maximum resistances of comparable magnitude. Alternatively, one dominant resistance layer achieves a much higher maximum resistance, when a low voltage bias is applied across all the layers, e.g., a Schottky barrier can be formed when the dominant resistance layer is oxidized.

The filament behavior under ramping positive voltage is shown in FIG. 3A and the right side of FIG. 2. A positive voltage is applied to the auxiliary resistance layer 112 (e.g. TiO₂), while a negative voltage is applied to the dominant resistance layer 110 (e.g. HfO₂). Oxygen ions 130 are gradually pulled up to the auxiliary resistance layer 112 under ramping positive voltage, and a filament 134 is formed in the dominant resistance layer 110 from oxygen vacancies 132. The resistance of the variable resistance layer 114 decreases due to the formation of the filament 134, and the current therefore trends up to Point B. This is known as the “SET” operation, marked as Region I in FIG. 2. As the voltage continues to increase, the resistance of the auxiliary resistance layer 112 increases as it receives oxygen ions 130 from the dominant resistance layer 110. The current therefore decreases from Point B to Point C. This can be regarded as “RESET after SET” operation, marked as Region II in FIG. 2. However, continuing to ramp up the (positive) voltage will cause the breakdown of the auxiliary resistance layer 112, with a corresponding current surge, marked as Region III in FIG. 2. The breakdown of the auxiliary resistance layer 112 would be able to carry current up to a defined limit (i.e. Point D), determined by an external current limiter during the filament formation step.

The filament behavior under ramping negative voltage is shown in FIG. 3B and the left side of FIG. 2. A negative voltage is applied to the auxiliary resistance layer 112 (e.g. TiO₂), while a positive voltage is applied to the dominant resistance layer 110 (e.g. HfO₂). Oxygen ions 136 are gradually pulled back to the dominant resistance layer 110 under ramping negative voltage, and a filament 140 is formed in the auxiliary resistance layer 112 from oxygen vacancies 138. The increased resistance of the dominant resistance layer 110 is greater than the decreased resistance of the auxiliary resistance layer 112, so that the current trends down from Point E to Point F. This is known as the “RESET” operation, marked as Region IV in FIG. 2. Further (negative) voltage ramping could cause a post-RESET resistance reduction (“SET after RESET”) or possibly a breakdown of the dominant resistance layer 110, resulting in the final current jump.

In view of the above, the resistance memory of the disclosure can be a single-level cell (SLC) memory, and the operation window W1 thereof includes Region I (SET region) and Region IV (RESET region), as shown in FIG. 2.

Further, the resistance memory of the disclosure has implications for multi-level cell (MLC) operation, making use of more than two resistance states. For example, at least six resistance states (Point A to Point F), representing log₂(6)=2.6 bits, are shown in FIG. 2. More resistance states can be obtained by optimally controlling the applied voltages to the dominant resistance layer 110 and the auxiliary resistance layer 112. For example, a resistance state may be present between Point A and Point B or between Point E and Point F. In other words, the resistance memory of the disclosure gives potential for adding more resistance states, and the MLC operation window W2 thereof includes Region I (SET region), Region II (RESET and SET region), Region III and Region VI (RESET region), as shown in FIG. 2.

### Second Embodiment

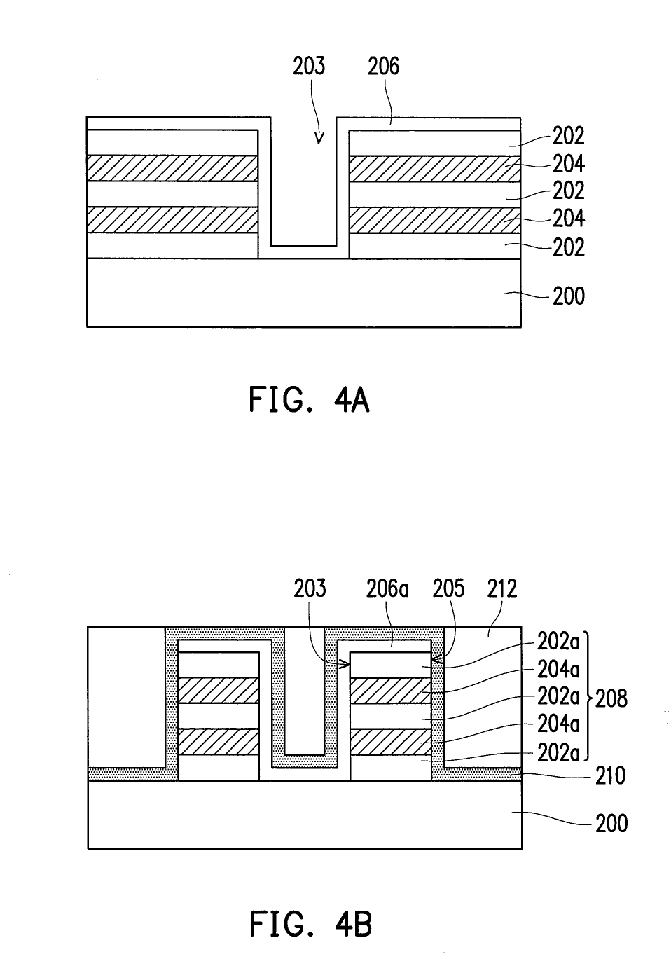

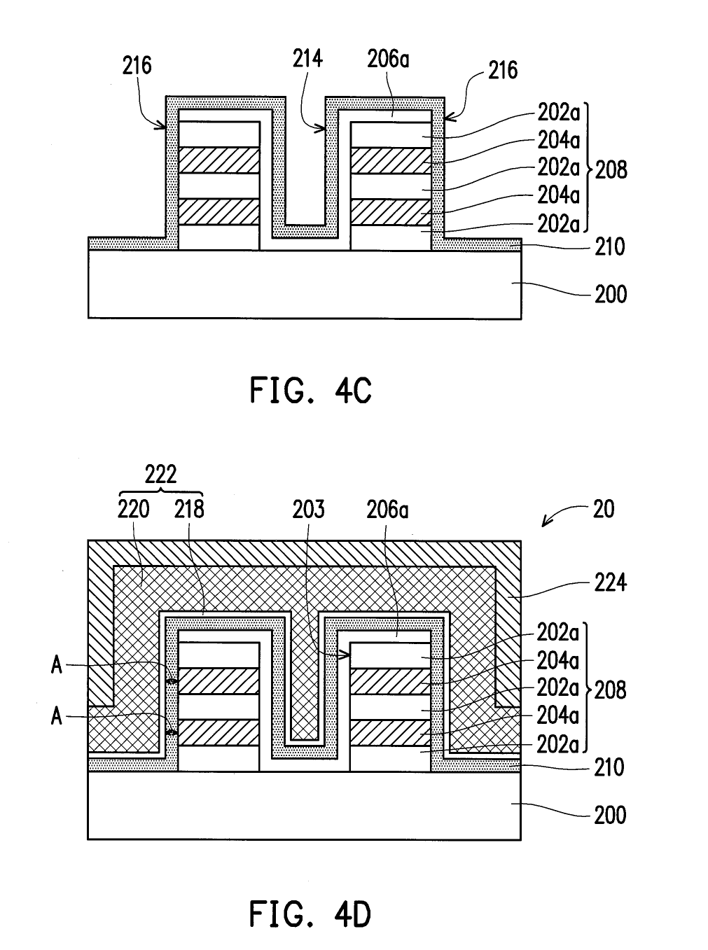

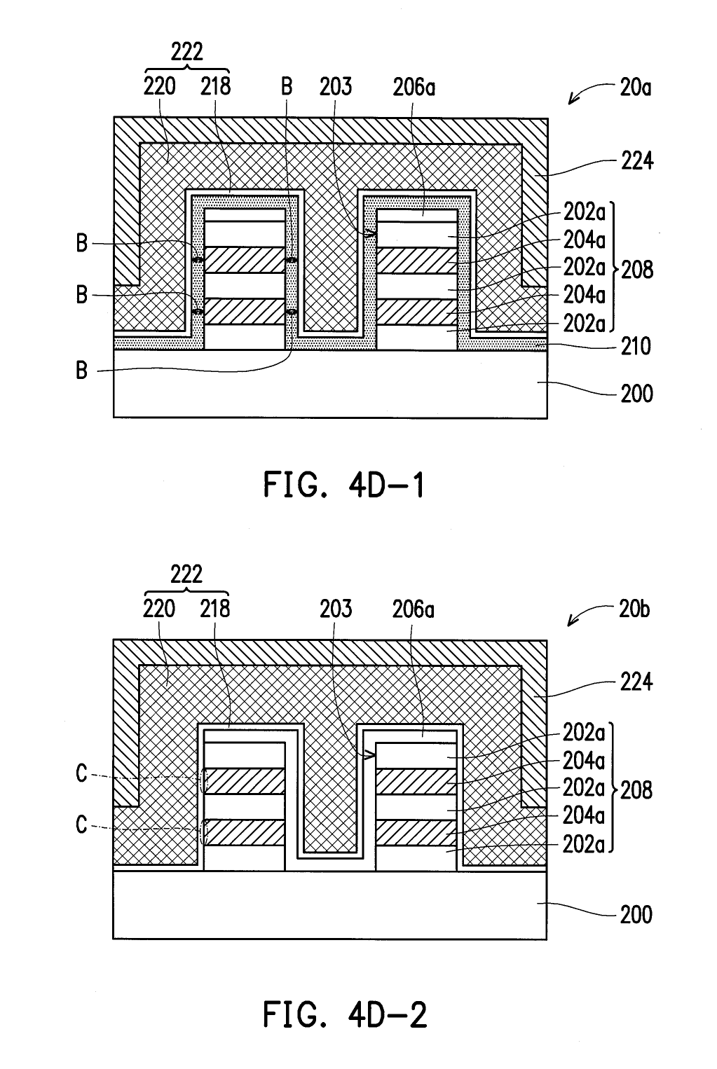

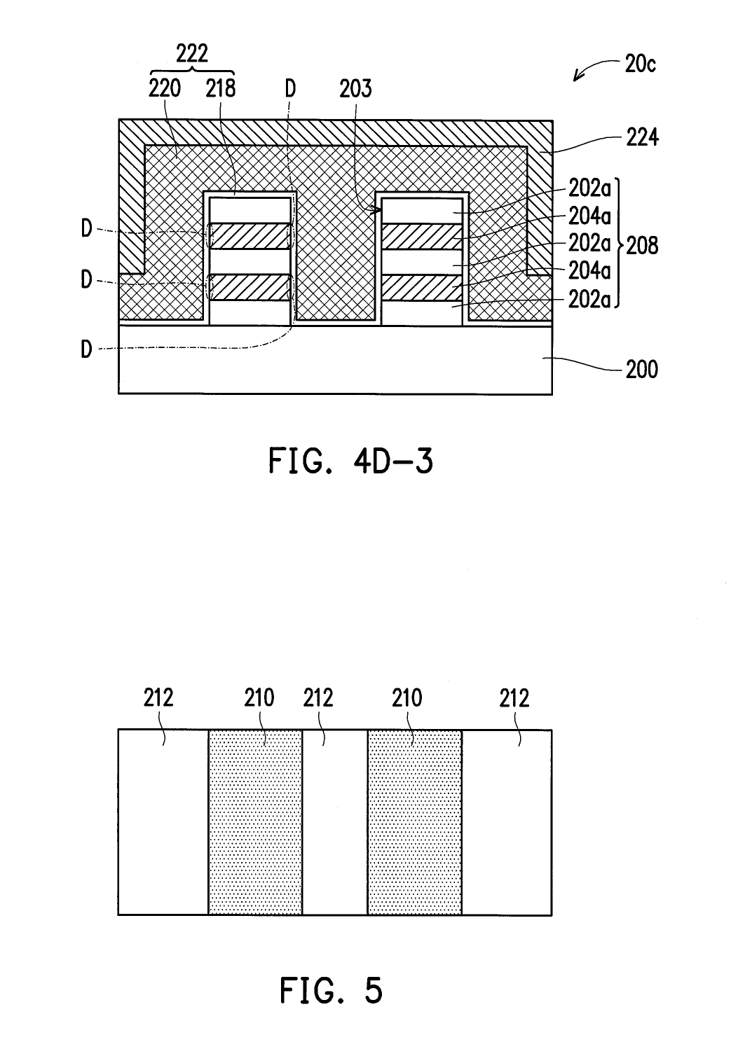

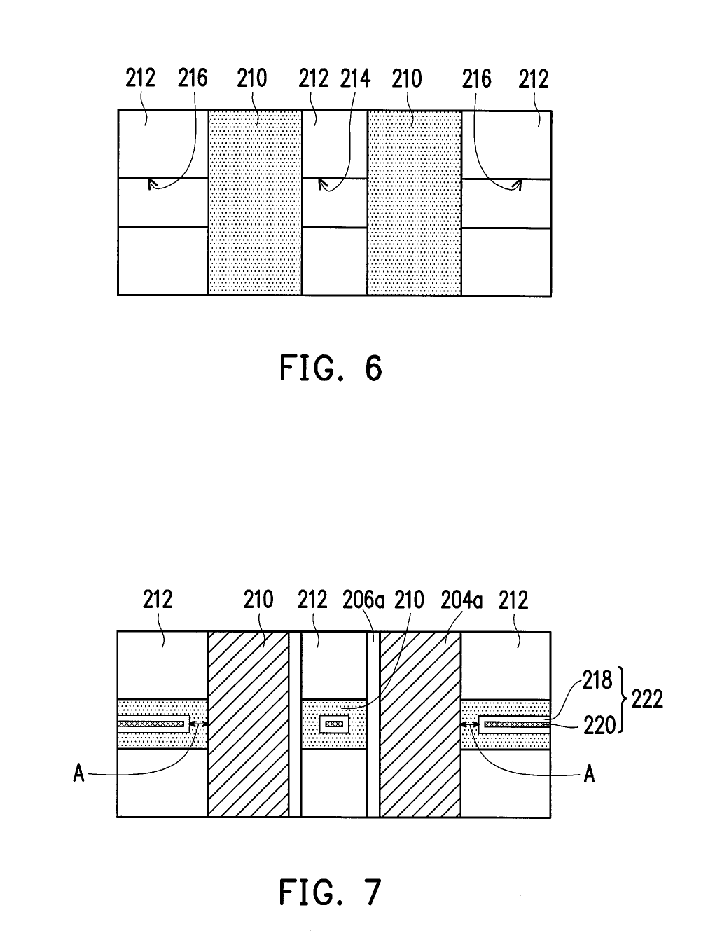

FIG. 4A to FIG. 4D are schematic cross-sectional views illustrating a method of forming a resistance memory array according to a second embodiment of the disclosure. FIG. 5 is a schematic top view of FIG. 4B. FIG. 6 is a schematic top view of FIG. 4C.

Referring to FIG. 4A, a plurality of insulation layers 202 and a plurality of bit line layers 204 arranged alternately are formed on a substrate 200, and a barrier opening 203 is formed through the bit line layers 204 and the insulation layers 202. The barrier opening 203 can be an opening. The insulation layers 202 include SiOx, AlOx, SiN or SiON. The bit line layers 204 include Al. Thereafter, an optional barrier layer 206 is conformably formed on the substrate 200 to at least cover the uppermost insulation layer 202 and the inner side of the barrier opening 203. The barrier layer 206 can be a dielectric layer. The barrier layer 206 includes SiOx, AlOx, SiN or SiON. Furthermore, the material of the barrier layer 206 can be the same or different from that of the insulation layers 202. The method of forming the barrier layer 206 includes performing a chemical vapour deposition (CVD) process.

Referring to FIG. 4B and FIG. 5, a patterning step is performed to form at least two stacked structures 208 on the substrate 200 with the barrier opening 203 between the stacked structures 208 and active interface openings 205 at outer sides of the stacked structures 208. The active interface openings 205 can be an opening. Each of the patterned stacked structures 208 includes a plurality of insulation layers 202a and a plurality of bit line layers 204a arranged alternately on the substrate 200. Further, during the same patterning step, the patterned barrier layer 206a is formed along the inner side of the barrier opening 203 and on the tops of the stacked structures 208. The barrier layer 206a can be a dielectric layer. The patterning step includes performing trench refill, photolithography and etching processes.

Thereafter, an optional passivation layer 210 is formed on the substrate 200 to cover the stacked structures 208. The passivation layer 210 can be a dielectric layer. The passivation layer 210 includes SiOx, AlOx, SiN or SiON. Furthermore, the material of the passivation layer 210 can be the same or different from that of the barrier layer 206a. The method of forming the passivation layer 210 includes performing a CVD process. Afterwards, a dielectric layer 212 is formed between and outside of the stacked structures 208. In other words, the space between and outside of the stacked structures 208 is filled with the dielectric layer 212. The dielectric layer 212 includes SiOx, AlOx, SiN or SiON. Furthermore, the material of the dielectric layer 212 can be the same or different from that of the barrier layer 206a or the passivation layer 210. The method of forming the dielectric layer 212 includes depositing a dielectric material layer (not shown) on the substrate 200 and then performing an etching back or a chemical mechanical polishing (CMP) process to the dielectric material layer until the top of the passivation layer 210 is exposed.

Referring to FIG. 4C and FIG. 6, a first word line trench opening 214 is formed in the dielectric layer 212 between the stacked structures 208, and at the same time, two second word line trench openings 216 are formed in the dielectric layer 212 respectively at outer sides of the stacked structures 208. The first word line trench opening 214 or the second word line trench openings 216 can be an opening. The method of forming the first and second word line trench openings 214 and 216 includes performing photolithography and etching processes to remove a portion of the dielectric layer 212.

Referring to FIG. 4D, a variable resistance layer 222 including at least one dominant resistance layer 218 and at least one adjacent auxiliary resistance layer 220 is formed to cover the stacked structures 208 and fill in the first and second word line trench openings 214 and 216. The dominant resistance layer 218 and the auxiliary resistance layer 220 form a closed ion exchange system, exchanged ions are comparably mobile in each of the dominant resistance layer 218 and the auxiliary resistance layer 220, and the maximum resistance of the dominant resistance layer 218 is higher than that of the auxiliary resistance layer 220. The materials of the dominant resistance layer 218 and the auxiliary resistance layer 220 have been described in the first embodiment, and the details are not iterated herein. Thereafter, a word line layer 224 is formed on the variable resistance layer 222. The word line layer 224 includes a conductive material, such as metal. The method of forming each of the dominant resistance layer 218, the auxiliary resistance layer 220 and the word line layer 224 includes performing a CVD process. The resistance memory array 20 of the second embodiment is thus completed.

The structure of the resistance memory array of the second embodiment is illustrated with reference to FIG. 4D. As shown in FIG. 4D, the resistance memory array 20 includes at least two separate stacked structures 208, a variable resistance layer 222 and a word line layer 224. The stacked structure 208 are disposed on a substrate 200, wherein each stacked structure 208 includes a plurality of insulation layers 202a and a plurality of bit line layers 204a arranged alternately, and a barrier opening 203 is formed between the stacked structures 208. The variable resistance layer 222 including at least one dominant resistance layer 218 and at least one adjacent auxiliary resistance layer 220 is disposed on the substrate 200 and covers the stacked structures 208. The dominant resistance layer 218 and the auxiliary resistance layer 220 form a closed ion exchange system, exchanged ions are comparably mobile in each of the dominant resistance layer 218 and the auxiliary resistance layer 220, and the maximum resistance of the dominant resistance layer 218 is higher than that of the auxiliary resistance layer 220. The word line layer 224 is disposed on the variable resistance layer 222. In this embodiment, the resistance memory array 20 further includes a barrier layer 206a and a passivation layer 210. The passivation layer 210 is disposed between each stacked structure 208 and the variable resistance layer 222. The barrier layer 206a covers the inner side of the barrier opening 203 between the stacked structures 208 and the tops of the stacked structures 208. Further, the passivation layer 210 covers the barrier layer 206a.

FIG. 7 is a schematic top view within one plane of the bit line layers according to the second embodiment of the disclosure. In the resistance memory array 20 of the second embodiment, the barrier layer is thicker at one side than the other side of each bit line layer 204a, so that the areas with a thinner barrier layer serve as switching areas, shown as arrows A in FIG. 4D and FIG. 7. Both the barrier layer 206a and the passivation layer 210 can be regarded as the barrier layer of the variable resistance layer 222. The barrier layer is thicker at one side than the other side of each bit line layer 204a due to the disposition of the barrier layer 206a. In this case, a single-side switching is operated, which enables the resistance memory array to function more stably. Besides, since the barrier layer of the variable resistance layer 222 is disposed in this embodiment, the dominant resistance layer 218 and the auxiliary resistance layer 220 can be formed in a reverse order of FIG. 4D. For example, the auxiliary resistance layer 220 can be formed prior to the dominant resistance layer 218.

FIG. 4D-1 is a schematic cross-sectional view of another resistance memory array according to the second embodiment of the disclosure. The same process steps as described in FIG. 4A to FIG. 4D are followed except that the step of forming the barrier layer 206a is omitted. The resistance memory array 20a is thus completed. In the resistance memory array 20a of this embodiment, the passivation layer 210 as a barrier layer has a substantially equal thickness at both sides of each bit line layer 204a, so that a double-side switching is operated, wherein the switching areas are shown as arrows B in FIG. 4D-1. Besides, since the barrier layer of the variable resistance layer 222 is disposed in this embodiment, the dominant resistance layer 218 and the auxiliary resistance layer 220 can be formed in a reverse order of FIG. 4D-1. For example, the auxiliary resistance layer 220 can be formed prior to the dominant resistance layer 218.

FIG. 4D-2 is a schematic cross-sectional view of yet another resistance memory array according to the second embodiment of the disclosure. The same process steps as described in FIG. 4A to FIG. 4D are followed except that the step of forming the passivation layer 210 is omitted. The resistance memory array 20b is thus completed. In the resistance memory array 20b of this embodiment, the barrier layer 206a is disposed at one side of each bit line layer 204a, so that the areas without the barrier layer 206a (i.e. the interfaces between each bit line layer 204a and the variable resistance layer 222) serves as switching areas, shown as dotted line regions C in FIG. 4D-2. Besides, in this embodiment, the barrier layer 206a is disposed at one side of each bit line layer 204a. That is, the other side of each bit line layer 204a is exposed to the variable resistance layer 222. In this case, the dominant resistance layer 218 is required to be formed prior to the auxiliary resistance layer 220, so as to prevent each bit line layer 204a from contacting the auxiliary resistance layer 220 to cause a short circuit.

FIG. 4D-3 is a schematic cross-sectional view of still another resistance memory array according to the second embodiment of the disclosure. The same process steps as described in FIG. 4A to FIG. 4D are followed except that the steps of forming the barrier layer 206a and the passivation layer 210 are omitted. The resistance memory array 20c is thus completed. In the resistance memory array 20c of this embodiment, no barrier layer is disposed beside each bit line layer 204a, so that the interfaces between each bit line layer 204a and the variable resistance layer 222 serve as switching areas, shown as dotted line regions D in FIG. 4D-3. Besides, in this embodiment, no barrier layer is disposed beside each bit line layer 204a. That is, either side of each bit line layer 204a is exposed to the variable resistance layer 222. In this case, the dominant resistance layer 218 is required to be formed prior to the auxiliary resistance layer 220, so as to prevent each bit line layer 204a from contacting the auxiliary resistance layer 220 to cause a short circuit.

In summary, in the resistance memory of the disclosure, the variable resistance layer includes at least two layers which mutually exchanged ions, thereby changing the resistance. The resistance range is wider when the at least two layers are oxides of different metals. Besides, the novel resistance memory based on ionic exchange can serve as a multi-level memory. Further, the method of the disclosure is simple and can be compatible with the existing memory processes.

The disclosure has been disclosed above in the preferred embodiments, but is not limited to those. It is known to persons skilled in the art that some modifications and innovations may be made without departing from the spirit and scope of the disclosure. Therefore, the scope of the disclosure can be defined by the following claims.

What is claimed is:

1. A resistance memory cell, comprising:
A variable resistance layer including at least one dominant resistance layer and at least one adjacent auxiliary resistance layer, wherein the at least one dominant resistance layer and the at least one adjacent auxiliary resistance layer in totality form a closed ion exchange system, exchanged ions are comparably mobile in each of the at least one dominant resistance layer and the at least one auxiliary resistance layer and a maximum resistance of the at least one dominant resistance layer is higher than a maximum resistance of the at least one auxiliary resistance layer.

2. The resistance memory cell of claim 1, wherein each of the at least one dominant resistance layer and the at least one auxiliary resistance layer comprises an oxide, and each exchanged ion comprises oxygen.

3. The resistance memory cell of claim 2, wherein the at least one dominant resistance layer comprises HfO₂, ZrO₂, Al₂O₃ or Ta₂O₅.

4. The resistance memory cell of claim 2, wherein the at least one auxiliary resistance layer comprises TiO₂, TaOₓ or TiO_{y}, where x is less than 2.5 and y is less than 2.

5. The resistance memory cell of claim 1, wherein the at least one dominant resistance layer comprises an oxide, the at least one auxiliary resistance layer comprises a chalcogenide or oxide doped with a metal, and each exchanged ion comprises the metal.

6. The resistance memory cell of claim 5, wherein the at least one dominant resistance layer comprises HfO₂, ZrO₂, Al₂O₃ or Ta₂O₅.

7. The resistance memory cell of claim 5, wherein the at least one auxiliary resistance layer comprises one of SiO₂, GeTe, GeSe and GeS each doped with the metal, and the metal comprises Cu or Ag.

8. A method of forming a resistance memory array, comprising:
forming a plurality of insulation layers and a plurality of bit line layers arranged alternately on a substrate, wherein at least one barrier opening is formed through the insulation layers and the bit line layers;
patterning the insulation layers and the bit line layers, so as to form at least two stacked structures with the barrier opening therebetween;
forming a dielectric layer between and outside of the stacked structures;
forming a first word line trench opening in the dielectric layer between the stacked structures and forming two second word line trench openings in the dielectric layer respectively at outer sides of the stacked structures;
forming a variable resistance layer including at least one dominant resistance layer and at least one adjacent auxiliary resistance layer to cover the stacked structures and fill in the first and second word line trench openings; and
forming a word line layer on the variable resistance layer.

9. The method of claim 8, wherein each of the at least one dominant resistance layer and the at least one auxiliary resistance layer comprises an oxide, and each exchanged ion comprises oxygen.

10. The method of claim 9, wherein the at least one dominant resistance layer comprises HfO₂, ZrO₂, Al₂O₃ or Ta₂O₅.

11. The method of claim 9, wherein the at least one auxiliary resistance layer comprises TiO₂, TaOₓ or TiO_{y}, where x is less than 2.5 and y is less than 2.

12. The method of claim 8, wherein the at least one dominant resistance layer comprises oxide, the at least one auxiliary resistance layer comprises a chalcogenide or oxide doped with a metal, and each exchanged ion comprises the metal.

13. The method of claim 12, wherein the at least one dominant resistance layer comprises HfO₂, ZrO₂, Al₂O₃ or Ta₂O₅.

14. The method of claim 12, wherein the at least one auxiliary resistance layer comprises one of SiO₂, GeTe, GeSe and GeS each doped with the metal, and the metal comprises Cu or Ag.

15. The method of claim 8, wherein the dominant resistance layer is formed below the adjacent auxiliary resistance layer.

16. The method of claim 8, further comprising, after the step of forming the first and second word line trench openings and before the step of forming the variable resistance layer, forming a passivation layer to cover the stacked structures.

17. The method of claim 16, wherein the dominant resistance layer is formed below the adjacent auxiliary resistance layer.

18. The method of claim 16, wherein the dominant resistance layer is formed above the adjacent auxiliary resistance layer.

19. The method of claim 16, further comprising, after the step of forming the insulation layers and the bit line layers and before the step of patterning the insulation layers and the bit line layers, forming a barrier layer to at least cover an inner side of the first word line trench opening and tops of the stacked structures.

20. The method of claim 19, wherein the dominant resistance layer is formed below the adjacent auxiliary resistance layer.

21. The method of claim 19, wherein the dominant resistance layer is formed above the adjacent auxiliary resistance layer.

22. The method of claim 8, wherein the at least one dominant resistance layer and the at least one auxiliary resistance layer in totality form a closed ion exchange system, exchanged ions are comparably mobile in each of the at least one dominant resistance layer and the at least one auxiliary resistance layer, and a maximum resistance of the at least one dominant resistance layer is higher than a maximum resistance of the at least one auxiliary resistance layer.

23. A resistance memory array, comprising:
at least two separate stacked structures, disposed on a substrate, wherein each stacked structure comprises a plurality of insulation layers and a plurality of bit line layers arranged alternately, and a barrier opening is formed between the stacked structures;
a variable resistance layer, including at least one dominant resistance layer and at least one adjacent auxiliary resistance layer, disposed on the substrate and covering the stacked structures; and
a word line layer, disposed on the variable resistance layer.

24. The resistance memory array of claim 23, wherein the at least one dominant resistance layer and the at least one auxiliary resistance layer comprises an oxide, and each exchanged ion comprises oxygen.

25. The resistance memory array of claim 24, wherein the at least one dominant resistance layer comprises HfO₂, ZrO₂, Al₂O₃ or Ta₂O₅.

26. The resistance memory array of claim 24, wherein the at least one auxiliary resistance layer comprises TiO₂, TaOₓ or TiOₓ, where x is less than 2.5 and y is less than 2.

27. The resistance memory array of claim 23, wherein the at least one dominant resistance layer comprises an oxide, the at least one auxiliary resistance layer comprises a chalcogenide or oxide doped with a metal, and each exchanged ion comprises the metal.

28. The resistance memory array of claim 27, wherein the at least one dominant resistance layer comprises HfO₂, ZrO₂, Al₂O₃ or Ta₂O₅.

29. The resistance memory array of claim 27, wherein the at least one auxiliary resistance layer comprises one of SiO₂, GeTe, GeSe and GeS each doped with the metal, and the metal comprises Cu or Ag.

30. The resistance memory array of claim 23, wherein the dominant resistance layer is formed below the adjacent auxiliary resistance layer.

31. The resistance memory array of claim 23, further comprising a passivation layer disposed between each stacked structure and the variable resistance layer.

32. The resistance memory array of claim 31, wherein the dominant resistance layer is formed below the adjacent auxiliary resistance layer.

33. The resistance memory array of claim 31, wherein the dominant resistance layer is formed above the adjacent auxiliary resistance layer.

34. The resistance memory array of claim 31, further comprising a barrier layer covering an inner side of the barrier opening between the stacked structures and tops of the stacked structures, and the passivation layer covering the barrier layer.

35. The resistance memory array of claim 34, wherein the dominant resistance layer is formed below the adjacent auxiliary resistance layer.

36. The resistance memory array of claim 34, wherein the dominant resistance layer is formed above the adjacent auxiliary resistance layer.

37. The resistance memory array of claim 23, wherein the at least one dominant resistance layer and the at least one auxiliary resistance layer in totality form a closed ion exchange system, exchanged ions are comparably mobile in each of the at least one dominant resistance layer and the at least one auxiliary resistance layer, and a maximum resistance of at least one dominant resistance layer is higher than a maximum resistance of at least one auxiliary resistance layer.
